(19) United States
(12) Patent Application Publication
(10) Pub. No.: US 2006/0258023 A1
(43) Pub. Date: Nov. 16, 2006

(54) Method and system for improving integrated circuit manufacturing yield

(75) Inventors: Kirk Rolofson, Gresham, OR (US); Brent Gwynn, Portland, OR (US); Michael Fenrick, Portland, OR (US)

Correspondence Address: LSI LOGIC CORPORATION, 1621 BARBER LANE, MS: D-106, MILPITAS, CA, 95035, US

(73) Assignee: LSI LOGIC CORPORATION, Milpitas, CA (US)

(21) Appl. No.: 11/125,863

(22) Filed: May 10, 2005

(51) Int. Cl. H01L 21/66; G06K 9/00

(52) U.S. Cl. 438/14; 382/145

(57) ABSTRACT

A lithographic scanner collects surface height information concurrently with conducting a lithographic scan process. A defect identification module identifies wafers having a surface height metric greater than a determined threshold. The identified wafers may be separated for rework to correct the surface defects such as hotspots and improve manufacturing yield without requiring additional equipment. In one embodiment, the surface height metric is a maximum variation from a moving average surface height. In one embodiment, yield data is correlated with surface height information to determine a threshold value corresponding to defective circuit die.

### BACKGROUND OF THE INVENTION

1. Field of the Invention

The present invention relates generally to methods and systems for improving semiconductor manufacturing yield, and more particularly to methods and systems for reducing defects related to wafer hotspots.

2. Description of the Related Art

A typical integrated circuit is formed on a substrate wafer made of silicon or another semiconductor, such as gallium arsenide (GaAs) and indium phosphide (InP). The substrate undergoes a variety of processes such as layering, oxidation, etching, and doping in order to form transistors and conductive paths thereon. Layering typically includes depositing layers of silicon or metal on the semiconductor and selectively processing such layers using lithographic techniques.

FIG. 1 is a block diagram that provides a simplified representation of a prior art IC fabrication system 100. The prior art IC fabrication system 100 includes a variety of tools configured to enable formation of electronic structures on wafers. Typically, an array of integrated circuit die are formed on the wafers and subsequently cut and packaged into individual integrated circuits or “chips”. The electronic structures formed on the wafers may include many layers of material including active layers used to form devices such as transistors, and passive layers to interconnect the transistors.

The processes used to form active devices such as transistors are often referred to as ‘front end’ processes in that they occur at the front end of the IC fabrication sequence, while the processes used to form the interconnect layers are known as ‘back end’ processes. Front end processes selectively expose or ‘dope’ regions of the wafer substrate to ions at specific concentrations in order to control the electrical properties of the active devices. Back end processes typically deposit alternating layers of conductive and nonconductive material in order to selectively interconnect the active devices.

Both front end processes and back end processes frequently use lithography techniques to control the areas that are subjected to each process step. For example, with a back end process, a layer of conductive or non-conductive material may be deposited with a deposition tool 110 and subsequently coated with a thin layer of light sensitive ‘resist’ with another deposition tool 110 such as a photoresist spinner.

The light sensitive resist may be exposed in a designed pattern via a template or reticle within a stepper (not shown) or a scanner 120. Steppers expose an entire region or field of the wafer with a single exposure. In contrast, scanners scan the reticle with a focused beam of light such as a laser and thereby expose the designed pattern onto the light sensitive resist. Both steppers and scanners typically expose a field corresponding to one or more circuit die before advancing to a different area on the wafer.

After exposure, the exposed or unexposed regions of resist are washed or etched away to form the designed protective pattern on the wafer. Subsequently, a front end layer is typically subjected to implantation of electrically active ions in order to form transistors or other active devices. In contrast, a back end layer may be etched to remove the exposed areas of the conductive or non-conductive layer. The tools used to perform such processes are represented in FIG. 1 as the implant or etching tools 130.

After each layer of the wafer is selectively processed, the protective resist pattern may be removed by one or more resist removal tools 140 before repeating the entire cycle to form an additional layer, or implant additional device regions with ions. IC fabrication processes often involve the formation of 20 or more layers on each wafer each of which requires a cycle of deposition, exposure, and removal of a light sensitive resist.

Due to the small geometries involved, the tools and processes associated with IC fabrication systems are known to be extremely sensitive to contamination from dust or other particles. Consequently, great care is exercised in removing contaminates from an IC manufacturing environment. However, since human operation is typically involved and geometry sizes continue to shrink, contamination remains a pressing issue despite constant advances in environmental purification and scrubbing systems.

One specific issue related to contamination (that is addressed by the present invention) is that the scanner 120 or similar tool is typically restricted to a very short depth of focus. As a result, any contamination of particles may result in an elevated ‘hotspot’ where the exposed image or pattern is out of focus resulting in a defective pattern of protective resist at the wafer hotspot. In particular, some deposition tools 110 such as thin film deposition tools may accumulate contamination particles between cleanings. Some of the contamination may adhere to the backside of a wafer resulting in an elevated hotspot during the scanning process. In some cases, the scanning tool may collect a contamination particle resulting in a repetitive hotspot.

Rather than processing the wafer(s) through all of the IC fabrication steps before detecting inoperable die, some fabrication facilities include one or more defect inspection tools 150 where wafers are inspected for flawed regions of protective resist. If a flawed region is found, the flawed layer of protective resist (and the layer having the hotspot) may be removed from the entire wafer by one or more rework tools 160.

However, due to the small geometries involved, the time and cost of complete inspection with the defect inspection tools is prohibitive. As a result, most facilities inspect a random sampling of wafers rather than each wafer. Consequently, many defects are not detected.

Accordingly, it would be an advancement in the art to provide a method and system for automatically detecting unfocused regions of resist concurrent with exposing the resist in a scanner. Once detected, such wafers could be subjected to rework to substantially eliminate circuit die failures due to wafer hotspots.

### SUMMARY OF THE INVENTION

The present invention has been developed in response to the present state of the art, and in particular, in response to the problems and needs in the art that have not yet been fully solved by currently available defect detection systems. Accordingly, the present invention has been developed to provide a method to automatically identify wafers having surface defects associated with hotspots.

In one aspect of the present invention, a method to improve integrated circuit manufacturing yield includes collecting surface height information for a wafer concurrent with conducting a lithographic scan process, identifying wafers having a surface height metric that is greater than a selected threshold, and reworking the identified wafers. The identified wafers may be manually or automatically routed to one or more rework tools to remove the defective layer. Reworking the identified wafers may include removing a layer of resist and scrubbing the wafer.

In one embodiment, the surface height metric is a variation of the surface height from a moving average of the surface height. The method may also include identifying a tool responsible for the variation in surface height. In one embodiment, yield data is analyzed to determine the selected threshold for a particular layer.

In another aspect of the present invention, a system to improve integrated circuit manufacturing yield, includes a lithographic scanner configured to collect surface height information for a wafer concurrent with conducting a lithographic scan process, a defect identification module configured to automatically identify wafers having a surface height metric that is greater than a selected threshold, and one or more tools configured to rework the identified wafers.

The present invention enables automatic identification of wafers with surface defects such as hotspots. Identification may be accomplished without requiring additional equipment or process steps. Consequently, the present invention provides benefits and advantages over the prior art.

Reference throughout this specification to features, advantages, or similar language does not imply that all of the features and advantages that may be realized with the present invention should be or are in any single embodiment of the invention. Rather, language referring to the features and advantages is understood to mean that a specific feature, advantage, or characteristic described in connection with an embodiment is included in at least one embodiment of the present invention. Thus, discussion of the features and advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize that the invention can be practiced without one or more of the specific features or advantages of a particular embodiment. In other instances, additional features and advantages may be recognized in certain embodiments that may not be present in all embodiments of the invention.

These features and advantages will become more fully apparent from the following description and appended claims, or may be learned by the practice of the invention as set forth hereinafter.

### BRIEF DESCRIPTION OF THE DRAWINGS

In order that the advantages of the invention will be readily understood, a more particular description of the invention briefly described above will be rendered by reference to specific embodiments that are illustrated in the appended drawings. Understanding that these drawings depict only typical embodiments of the invention and are not therefore to be considered to be limiting of its scope, the invention will be described and explained with additional specificity and detail through the use of the accompanying drawings, in which:

FIG. 1 is a block diagram of a prior art IC fabrication system;

FIG. 2 is a block diagram depicting one embodiment of an IC fabrication system of the present invention;

FIG. 3 is a flow chart diagram depicting one embodiment of an IC fabrication method of the present invention;

FIG. 4 is a text-based diagram of example metrology data in accordance with the present invention; and

FIG. 5 is a text-based diagram depicting one embodiment of a wafer identification message of the present invention that corresponds to the example metrology data of FIG. 4.

### DETAILED DESCRIPTION OF THE INVENTION

Reference throughout this specification to “one embodiment,” “an embodiment,” or similar language means that a particular feature, structure, or characteristic described in connection with the embodiment is included in at least one embodiment of the present invention. Thus, appearances of the phrases “in one embodiment,” “in an embodiment,” and similar language throughout this specification may, but do not necessarily, all refer to the same embodiment.

Furthermore, the described features, advantages, and characteristics of the invention may be combined in any suitable manner in one or more embodiments. One skilled in the relevant art will recognize that the invention can be practiced without one or more of the specific features or advantages of a particular embodiment. In other instances, additional features and advantages may be recognized in certain embodiments that may not be present in all embodiments of the invention.

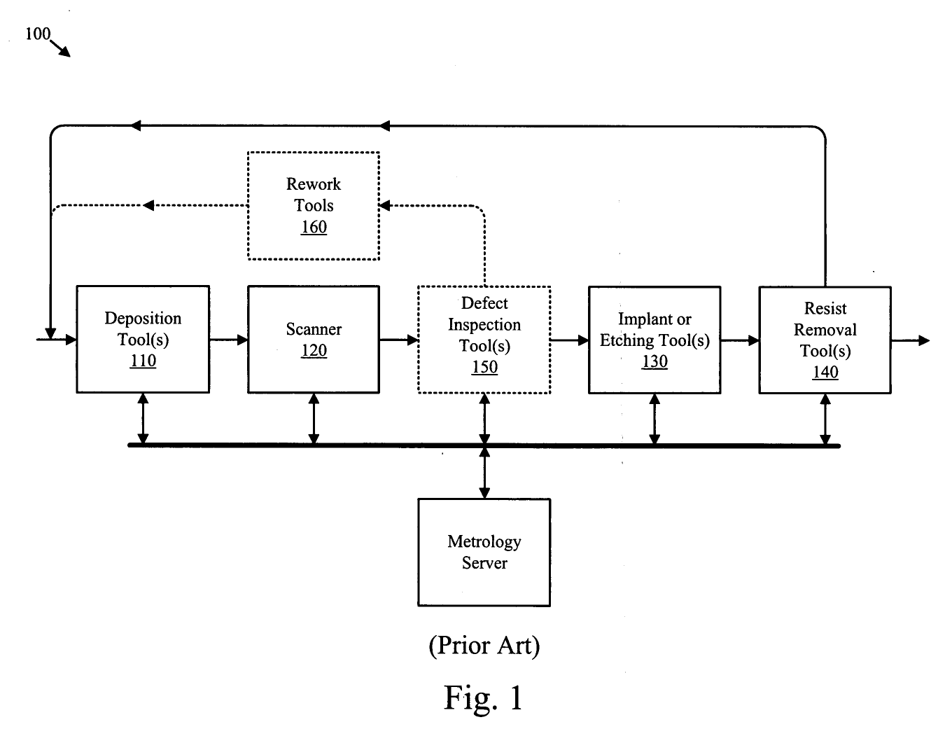

As detailed in the background section and shown in FIG. 1, prior art fabrication systems may include one or more defect inspection tools 150 that are used to detect resist pattern flaws and direct wafers having such flaws to rework. Once detected, the fabrication processes may be analyzed to find the cause or source of the contamination. However, the time required to inspect a wafer and the capital equipment and operator cost associated with the defect inspection tool 150 typically relegates defect inspection to randomly selected wafers.

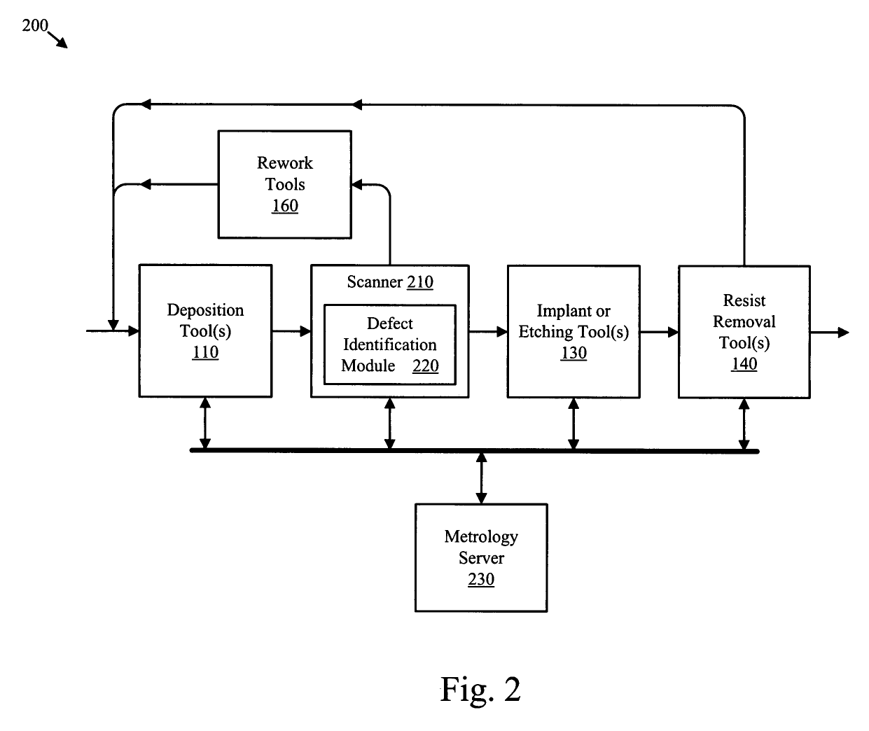

FIG. 2 is a block diagram depicting one embodiment of an IC fabrication system 200 of the present invention that addresses many of the issues described above. As depicted, the IC fabrication system 200 includes a scanner 210 with a defect identification module 220. Alternately, the defect identification module 220 may reside on a metrology server 230 that is in operable communication with the scanner 210. For illustrative purposes, the IC fabrication system 200 is depicted in a simplified abstracted form.

The deposition tools 110 are used to deposit functional material layers as needed as well as lithographic layers such as light sensitive resist. In one embodiment, the deposition tools 110 include chemical vapor deposition (CVD) tools and photoresist spinners that deposit a layer of resist by pouring the resist on a spinning wafer and spinning off excess resist. The layer of resist may be selectively exposed by the scanner 210.

The scanner 210 collects surface height information concurrent with conducting a lithographic scan of a wafer. In certain embodiments, the scanner 210 uses internal level sensing and/or interferometry data to compute a surface height metric useful for detection of hotspots. The surface height metric may be derived in real-time during a field scan or extracted from data saved to a repository such as the metrology server 230.

In certain embodiments, the scanner 210 provides a surface height metric that represents the variation in the current surface height from a moving average of the surface height. In one embodiment, the surface height metric is the maximum variation within a particular scan field. In another embodiment, the surface height metric is the maximum variation for an entire wafer.

The defect identification module 220 identifies wafers that have a surface height metric that is greater than a selected threshold. In one embodiment, the threshold is selected based on yield data of individual die from previous runs. By using a threshold that is highly correlated with inoperable die, wafers containing defective die may be automatically identified and separated for rework. In the depicted embodiment, the layer of resist is removed from identified wafers using the rework tools 160. Subsequently, a new layer of light sensitive material may be re-deposited on the wafers using the appropriate depositions tools 110 and then re-scanned by the scanner 210.

Wafers that are not selected for rework may be directed to the implant or etching tools 130 for additional processing. The implant or etching tools 130 alter exposed areas of material and thereby control the properties and geometries of the particular layers involved. Subsequently, the light sensitive resist used to selectively process a wafer with the implant or etching tools 130 may be removed by the resist removal tools 140. In some instances, the resist removal tools 140 and the rework tools 160 are the same tools.

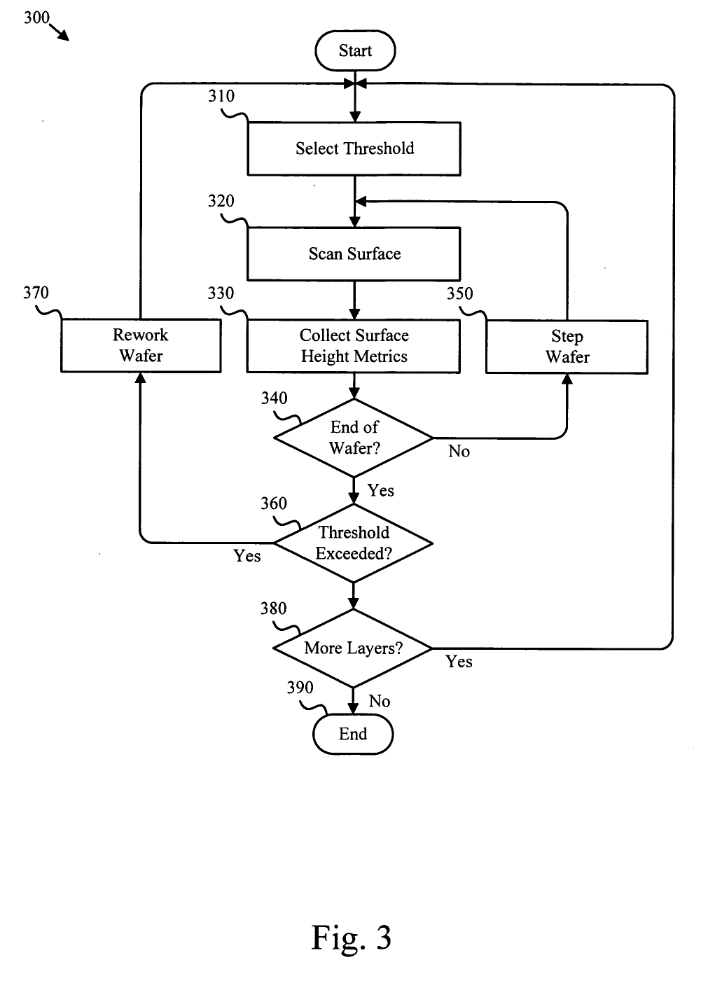

FIG. 3 is a flow chart diagram depicting one embodiment of an IC fabrication method 300 of the present invention. As depicted, the IC fabrication method 300 includes selecting 310 a threshold, scanning 320 a wafer surface, collecting 330 one or more surface height metrics, stepping 350 the wafer, and reworking 370 a wafer if the surface height metric exceeds the selected threshold. The IC fabrication method 300 improves wafer yield by automatically detecting wafers with hotspots associated with inoperable circuit die.

Selecting 310 a threshold may include offline or online analysis of yield data to ascertain a threshold beyond which integrated circuit die are nearly always defective. In the depicted embodiment, the selected threshold is layer specific. Using a layer specific threshold improves the accuracy of automatic detection of hotspots.

Scanning 320 a wafer surface may be accomplished by a scanner (such as the scanner 210) equipped to collect or generate surface height information concurrent with scanning a wafer to selectively expose light sensitive resist. Concurrently generating such information improves throughput in a fabrication facility in that a separate process step or tool is not needed to identify defective wafers.

The operation of collecting 330 one or more surface height metrics may include filtering or smoothing such data in order to separate long term height variations such as wafer tilt from short term variations due to particle contamination. In certain embodiments, collecting 330 one or more surface height metrics involves computing a difference between a moving average (representing long term variations) and a current surface height. In one embodiment, the difference is compared with maximum value for the field or wafer and the maximum value is updated if the difference is greater than the previous maximum. Using a maximum value enables the method 300 to immediately discard unneeded surface height information.

An end of wafer test 340 ascertains whether more fields need to be scanned on the wafer. If the end of the wafer has not been reached and more fields need to be scanned, the method proceeds by stepping 350 the wafer to a new region and repeating the scan surface operation 320. If the end of the wafer has been reached the depicted method proceeds to the threshold exceeded test 360.

The depicted threshold exceeded test 360 ascertains whether the specified threshold for the selected surface height metric has been exceeded. If the threshold has been exceeded, the method proceeds by reworking 370 the wafer and eventually repeating the depicted process to re-fabricate the same layer.

In one embodiment, the threshold exceeded test 360 is conducted for each field previous to the end of wafer test 340. In such an arrangement, a wafer scan may be aborted immediately upon occurrence of a hotspot that exceeds the threshold value for the layer. Aborting the wafer scan further improves fabrication throughput by eliminating unnecessary wafer scans.

If the threshold test 360 ascertains that the threshold has not been exceeded the method 300 proceeds to the more layers test 380. If more layers need to be fabricated, the method loops to the beginning and repeats the entire process. If all layers have been fabricated, the method ends 390.

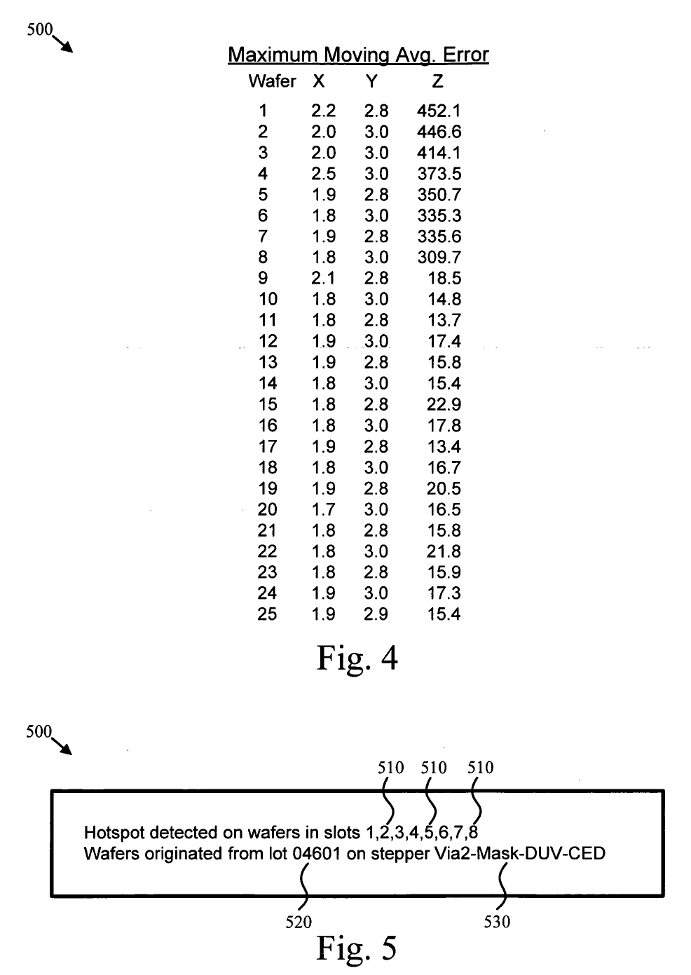

FIG. 4 is a text-based diagram of example metrology data 400 in accordance with the present invention. The metrology data 400 includes maximum values for each wafer in a lot of 25 wafers expressed in nanometers. The depicted metrology data 400 includes a maximum X, Y, and Z deviation (for the entire wafer) from a moving average value.

One can readily observe that the Z value for wafers 1 through 8 is significantly higher than the remaining wafers indicating significant hotspots on those wafers and the need for rework. A comparison of Z values for operable and inoperable die (due to hotspots) conducted by the applicants indicated that a threshold value between 200 and 250 nanometers (for the layer involved in this example) would separate wafers in need of rework from those that would probably not benefit from rework.

FIG. 5 is a text-based diagram of a wafer identification message 500 of the present invention that corresponds to the example metrology data of FIG. 4. As depicted, the wafer identification message 500 includes one or more wafer indicators 510, a lot or batch indicator 520, and a source indicator 530. The wafer identification message 500 may be presented to a tool operator and/or process engineer to facilitate rework of the identified wafers and resolution of the cause of the hotspots.

In one embodiment, the information within the wafer identification message 500 is used to automatically route the indicated wafers to one or more rework tools such as the rework tools 160 depicted in FIG. 1. The rework tools may strip off the protective resist, and chemically clean the wafer in order to prepare the wafer(s) for re-fabrication of the flawed layer.

The present invention improves integrated circuit fabrication. The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A method to improve integrated circuit manufacturing yield, the method comprising:
collecting surface height information for a wafer concurrent with conducting a lithographic scan process;
identifying wafers having a surface height metric that is greater than a selected threshold; and
reworking the identified wafers.

2. The method of claim 1, wherein reworking the identified wafers comprises removing at least one interconnection layer.

3. The method of claim 1, further comprising identifying a tool responsible for the surface height variation.

4. The method of claim 1, further comprising selecting the selected threshold based on yield data.

5. The method of claim 1, further comprising routing the identified wafers to a rework station.

6. The method of claim 1, wherein the surface height metric is a variation from a moving average surface height.

7. The method of claim 1, further comprising stepping a wafer to a new scanning position.

8. A system to improve integrated circuit manufacturing yield, the system comprising:
a lithographic scanner configured to collect surface height information for a wafer concurrent with conducting a lithographic scan process;
a defect identification module configured to automatically identify wafers having a surface height metric that is greater than a selected threshold; and
at least one tool configured to rework the identified wafers.

9. The system of claim 9, wherein the at least one tool comprises a tool for removing at least one interconnection layer.

10. The system of claim 9, wherein the defect identification module is further configured to automatically identify a tool responsible for the surface height variation.

11. The system of claim 9, further comprising a controller configured to route the identified wafers to a rework station.

12. The system of claim 9, wherein the surface height metric is a variation from a moving average surface height.

13. The system of claim 9, wherein the lithographic scanner is further configured to step a wafer to a new scanning position.

14. A system to improve integrated circuit manufacturing yield, the system comprising:
means for collecting surface height information for a wafer while concurrently conducting a lithographic scan process;
means for identifying wafers having a surface height metric that is greater than a selected threshold; and
means for reworking the identified wafers.

15. The system of claim 14, wherein the means for reworking the identified wafers comprises means for removing at least one interconnection layer.

16. The system of claim 14, further comprising means for routing the identified wafers to a rework station.

17. The system of claim 14, further comprising means for stepping a wafer to a new scanning position.

18. A machine readable medium comprising operations to improve integrated circuit manufacturing yield, the operations comprising:
collecting surface height information for a wafer while concurrently conducting a lithographic scan process;
identifying wafers having a surface height metric that is greater than a selected threshold; and
reworking the identified wafers.

19. The machine readable medium of claim 18, wherein the operations further comprise identifying a tool responsible for the surface height variation.

20. The machine readable medium of claim 18, wherein the surface height metric is a maximum variation for an entire wafer of a moving average surface height.

21. The machine readable medium of claim 18, wherein the operations further comprise stepping a wafer to a new scanning position.
